(19) United States
(12) Patent Application Publication
(10) Pub. No.: US 2024/0395697 A1
(43) Pub. Date: Nov. 28, 2024

(54) SEMICONDUCTOR DEVICE AND METHOD OF MANUFACTURING SAME

(71) Applicant: Kioxia Corporation, Tokyo (JP)

(72) Inventors: Mitsuhiko NODA, Kuwana Mie (JP); Masayoshi TAGAMI, Kuwana Mie (JP); Yoshiro SHIMOJO, Nagoya Aichi (JP)

(21) Appl. No.: 18/672,449

(22) Filed: May 23, 2024

(30) Foreign Application Priority Data
May 24, 2023 (JP) 2023-085789

(51) Int. Cl. H01L 23/522; H01L 21/768; H01L 23/00; H01L 23/532

(52) U.S. Cl. CPC H01L 23/5226; H01L 21/76802; H01L 21/76877; H01L 23/53257; H01L 24/08; H01L 24/80; H01L 2224/08145; H01L 2224/80895; H01L 2224/80896

(57) ABSTRACT

A semiconductor device includes a substrate, plugs, and interconnections. The plugs include a first plug and a second plug that are disposed above the substrate and extend in a first direction that crosses an upper surface of the substrate, and a third plug disposed above and electrically connected to the second plug and extending in the first direction. The interconnections include a first interconnection disposed above and electrically connected to the first plug, a second interconnection disposed below and electrically connected to the first plug, and a third interconnection disposed below and electrically connected to the second plug. The first interconnection contains copper. The third plug contains tungsten. An upper end of the second plug is different in level from an upper end of the first plug and a lower end of the second plug is same in level as a lower end of the first plug.

### CROSS-REFERENCE TO RELATED APPLICATION(S)

This application is based upon and claims the benefit of priority from Japanese Patent Application No. 2023-085789, filed May 24, 2023, the entire contents of which are incorporated herein by reference.

### FIELD

Embodiments described herein relate generally to a semiconductor device and a method of manufacturing the semiconductor device.

### BACKGROUND

When manufacturing a semiconductor device, it is preferable to reduce a chip size while preventing deterioration of electrical characteristics.

### BRIEF DESCRIPTION OF THE DRAWINGS

FIG. 1 illustrates a cross-sectional view of a semiconductor device according to an embodiment.

FIG. 2 illustrates a plan view of a stack of films of the semiconductor device according to the embodiment.

FIG. 3 illustrates an exploded view of electrode layers of the semiconductor device according to the embodiment.

FIG. 4 illustrates a transverse cross-sectional view of contact plugs of the semiconductor device according to the embodiment.

FIG. 5 illustrates a vertical cross-sectional view of the contact plugs of the semiconductor device according to the embodiment.

FIG. 6 illustrates a cross-sectional view of a columnar part of the semiconductor device according to the embodiment.

FIG. 7 illustrates a plan view of an interconnection layout of the semiconductor device according to the embodiment.

FIG. 8 illustrates a cross-sectional view of the interconnection layout of the semiconductor device according to the embodiment.

FIG. 9 is a cross-sectional diagram to explain a process step of a method of manufacturing the semiconductor device according to the embodiment.

FIG. 10 is a cross-sectional diagram to explain a process step, subsequent to that in FIG. 9, of the method of manufacturing the semiconductor device according to the embodiment.

FIGS. 11A through 11C are cross-sectional diagrams to explain detailed aspects of process steps of the method of manufacturing the semiconductor device according to the embodiment.

FIGS. 12A and 12B are cross-sectional diagrams to explain detailed aspects of process steps, subsequent to that in FIG. 11C, of the method of manufacturing the semiconductor device according to the embodiment.

FIGS. 13A and 13B are cross-sectional diagrams to explain process steps of a method of manufacturing a semiconductor device according to a first comparative example.

FIG. 14 illustrates a plan view of an interconnection layout of a semiconductor device which is manufactured using a method of manufacturing a semiconductor device according to a second comparative example.

FIG. 15 illustrates a cross-sectional view of the interconnection layout of the semiconductor device which is manufactured using the method of manufacturing the semiconductor device according to the second comparative example.

FIGS. 16A and 16B are cross-sectional diagrams to explain process steps, subsequent to that in FIG. 12B, of the method of manufacturing the semiconductor device according to the embodiment subsequent to FIG. 12B.

FIG. 17 illustrates a cross-sectional view of a semiconductor device according to a modified example.

### DETAILED DESCRIPTION

Embodiments provide a semiconductor device which makes it possible to reduce the chip size while preventing deterioration of the electrical characteristics, and a method of manufacturing the semiconductor device.

In general, according to an embodiment, a semiconductor device includes a substrate, plugs, and interconnections. The plugs include a first plug and a second plug that are disposed above the substrate and extend in a first direction that crosses an upper surface of the substrate, and a third plug disposed above and electrically connected to the second plug and extending in the first direction. The interconnections include a first interconnection disposed above and electrically connected to the first plug, a second interconnection disposed below and electrically connected to the first plug, and a third interconnection disposed below and electrically connected to the second plug. The first interconnection contains copper. The third plug contains tungsten. An upper end of the second plug is different in level from an upper end of the first plug and a lower end of the second plug is same in level as a lower end of the first plug.

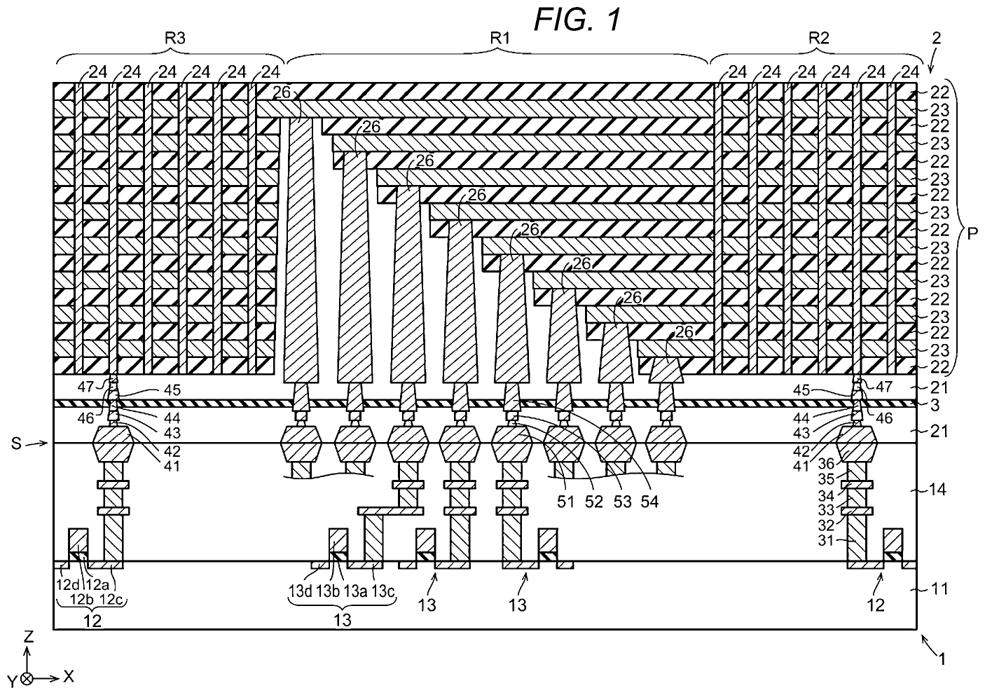

One or more embodiments of the present disclosure will hereinafter be described with reference to the drawings. In FIG. 1 through FIG. 17, the same elements are denoted by the same reference numerals, and redundant descriptions are omitted. In the present disclosure, a term “the same” used for expressing heights of a plurality of via plugs is not limited to when two things are exactly the same, and includes when two things are substantially the same.

FIG. 1 illustrates a cross-sectional view of a semiconductor device according to the embodiment.

The semiconductor device shown in FIG. 1 is, for example, a three-dimensional semiconductor memory device. The semiconductor device shown in FIG. 1 includes a circuit part 1 and an array part 2 disposed above the circuit part 1. The array part 2 includes a memory cell array including a plurality of memory cells. The circuit part 1 includes a CMOS circuit which controls the memory cell array. The semiconductor device shown in FIG. 1 is manufactured by bonding, for example, a circuit wafer including the circuit part 1 and an array wafer including the array part 2 to each other. FIG. 1 shows a bonding surface S between the circuit part 1 (in other words, the circuit wafer) and the array part 2 (in other words, the array wafer).

FIG. 1 shows X direction, Y direction, and Z direction perpendicular to each other. In the present specification, the +Z direction is treated as an upward direction, and the −Z direction is treated as a downward direction. The −Z direction may or may not coincide with a gravitational direction. The Z direction is an example of a first direction. The X direction is an example of a second direction crossing the first direction. The Y direction is an example of a third direction crossing the first direction and the second direction.

The circuit part 1 includes a substrate 11, a plurality of transistors 12, a plurality of transistors 13, and an interlayer insulating film 14. The circuit part 1 further includes a plurality of contact plugs 31, an interconnection layer 32, a plurality of via plugs 33, an interconnection layer 34, a plurality of via plugs 35, and a plurality of metal pads 36. The transistors 12 are each an example of a first transistor. The transistors 13 are each an example of a second transistor. The transistors 12 each include a gate insulating film 12a, a gate electrode 12b, a diffusion layer 12c, and a diffusion layer 12d. The transistors 13 each include a gate insulating film 13a, a gate electrode 13b, a diffusion layer 13c, and a diffusion layer 13d. Each of the interconnection layers 32, 34 may include a plurality of interconnections.

The array part 2 includes an interlayer insulating film 21, a stack of films P, a plurality of columnar parts 24, and a plurality of contact plugs 26. The contact plugs 26 are each an example of a third plug. The stack of films P includes a plurality of electrode layers 23 which are stacked in the Z direction, and are insulated from each other. More particularly, the stack of films P includes a plurality of insulating films 22 and the plurality of electrode layers 23 that are alternately stacked. The array part 2 further includes a plurality of metal pads 41, a plurality of via plugs 42, an interconnection layer 43, a plurality of via plugs 44, an interconnection layer 45, a plurality of via plugs 46, and a plurality of via plugs 47. The interconnection layer 43 is an example of a second interconnection. The via plugs 44 are each an example of a first plug. The interconnection layer 45 is an example of a first interconnection. The via plugs 46 are each an example of a fourth plug. The via plugs 47 are each an example of a fifth plug. Each of the interconnection layers 43, 45 may include a plurality of interconnections. The array part 2 further includes a plurality of metal pads 51, a plurality of via plugs 52, an interconnection layer 53, and a plurality of via plugs 54. The interconnection layer 53 is an example of a third interconnection. The via plugs 54 are each an example of a second plug. The interconnection layer 53 may include a plurality of interconnections.

First, the circuit part 1 will be described in detail. The substrate 11 is, for example, a semiconductor substrate such as a silicon substrate. In FIG. 1, an upper surface of the substrate 11 is made parallel to the X direction and the Y direction, and perpendicular to the Z direction.

The transistors 12 are disposed on the substrate 11. The gate insulating film 12a and the gate electrode 12b of each of the transistors 12 are stacked in order on the substrate 11. The diffusion layer 12c and the diffusion layer 12d of each of the transistors 12 are formed in the substrate 11 to sandwich a region below the gate electrode 12b. One of the diffusion layer 12c and the diffusion layer 12d functions as a source region. The other of the diffusion layer 12c and the diffusion layer 12d functions as a drain region. Each of the transistors 12 is electrically coupled to a corresponding one of the columnar parts 24 via the metal pads 36, 41 and so on. The transistors 12 may be disposed under areas R2, R3 where the columnar parts 24 are disposed in the stack of films P.

The transistors 13 are disposed on the substrate 11. The gate insulating film 13a and the gate electrode 13b of each of the transistors 13 are stacked in order on the substrate 11. The diffusion layer 13c and the diffusion layer 13d of each of the transistors 13 are formed in the substrate 11 to sandwich a region under the gate electrode 13b. One of the diffusion layer 13c and the diffusion layer 13d functions as a source region. The other of the diffusion layer 13c and the diffusion layer 13d functions as a drain region. Each of the transistors 13 is electrically coupled to a corresponding one of the contact plugs 26 via the metal pads 36, 51 and so on. At least some of the transistors 13 may be disposed under an area R1 where the contact plugs 26 are disposed in the stack of films P.

The interlayer insulating film 14 is disposed on the substrate 11 to cover the transistors 12 and the transistors 13. The interlayer insulating film 14 is, for example, a stack of films including a silicon oxide film and other insulating films.

As shown in FIG. 1, the contact plugs 31, the interconnection layer 32, the via plugs 33, the interconnection layer 34, the via plugs 35, and the metal pads 36 are disposed in order on the substrate 11. In the example shown in FIG. 1, each of the contact plugs 31 is electrically coupled to the diffusion layer 12c or the diffusion layer 13c of one of the transistors 12 or the transistors 13. Alternatively, each of one or more of the contact plugs 31 may be electrically coupled to the gate electrode 12b or 13b of one of the transistors 12 or the transistors 13.

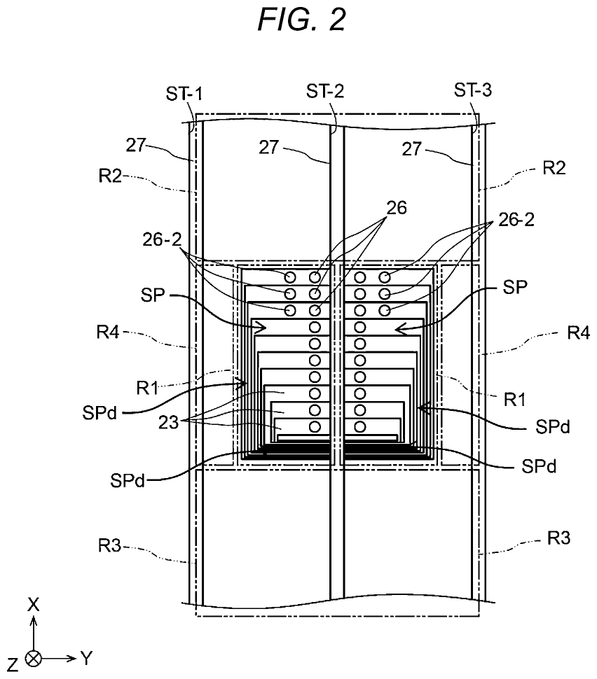

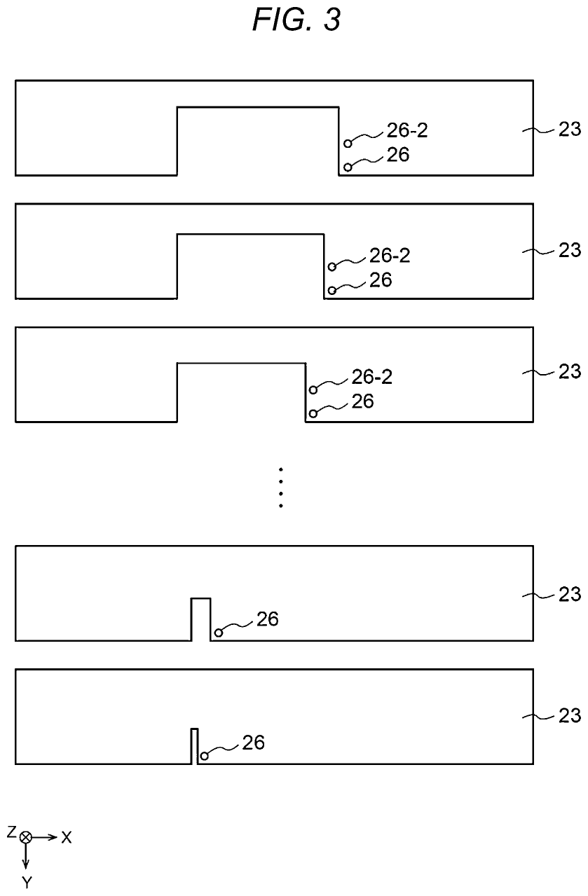

Next, the array part 2 will be described in detail. FIG. 2 illustrates a plan view of a stack of films of the semiconductor device according to the embodiment. FIG. 3 illustrates an exploded view of the electrode layers 23 of the semiconductor device according to the embodiment.

As shown in FIG. 1, the interlayer insulating film 21 of the array part 2 is disposed on the interlayer insulating film 14 of the circuit part 1. The interlayer insulating film 21 is sandwiched between the interlayer insulating film 14 and the stack of films P. The interlayer insulating example, a stack of films including a silicon oxide film and other insulating films.

The plurality of insulating films 22 described above and the plurality of electrode layers 23 described above are alternately stacked on the interlayer insulating film 21 above the substrate 11 to form the stack of films P. The plurality of electrode layers 23 are separated in the Z direction from each other. Each of the insulating films 22 is, for example, a silicon oxide film. Each of the electrode layers 23 is a metal layer, for example, a tungsten (i.e., W) layer. Each of the electrode layers 23 functions as, for example, a word line.

As shown in FIG. 1 and FIG. 2, the stack of films P has areas R1, R2, R3, and R4. The area R1 is an example of a first area. The area R2 is an example of a second area. The area R3 is an example of a third area. The area R4 is an example of a fourth area.

The area R1 is an area which is located above the contact plugs 26, and includes portions of the electrode layers 23 electrically coupled to the contact plugs 26. The area R1 corresponds to a hookup part in the semiconductor device. The area R2 is an area which is located at the +X direction side of the area R1, and is located above at least one of the via plugs 46. In other words, the area R2 is an area where some of the columnar parts 24 are disposed. The area R2 corresponds to a memory cell array part in the semiconductor device. The area R3 is an area which is located at the −X direction side of the area R1, and is located above at least another one of the via plugs 46. In other words, the area R3 is an area where other of the columnar parts 24 are disposed. The area R3 corresponds to the memory cell array part in the semiconductor device. The area R4 is an area which is located at the +Y direction side and/or the −Y direction side of the area R1, and electrically couples the electrode layers 23 in the area R2 and the electrode layers 23 in the area R3 to each other. In other words, the electrode layers 23 in the area R4 are continuous with the electrode layers 23 in the area R2 and the electrode layers 23 in the area R3. The area R4 may be also referred to as a bridge area.

As shown in FIG. 2, the stack of films P includes slits ST-1, ST-2, and ST-3. The slit ST-1 is an example of a first segmentation part, and the slit ST-2 is an example of a second segmentation part. The slit ST-2 is also an example of the first segmentation part, and in this case, the slit ST-3 is an example of the second segmentation part.

The slit ST-1 extends in the X direction to segmentalize the stack of films P. The slit ST-2 is located at the +Y direction side of the slit ST-1 across some of the contact plugs 26. The slit ST-2 extends in the X direction to segmentalize the stack of films P. The slit ST-3 is located at the +Y direction side of the slit ST-2 across the contact plugs 26. The slit ST-3 extends in the X direction to segmentalize the stack of films P.

The areas R1, R2, R3, and R4 of the stack of films P are segmentalized by the slits ST-1, ST-2, and ST-3. Inside the slits ST-1, ST-2, and ST-3, an insulating film 27 is disposed.

As shown in FIG. 1 through FIG. 3, the stack of films P in the area R1 is formed in a staircase pattern along the X direction and the Y direction. In other words, the stack of films P in the area R1 has a staircase structure along the X direction and the Y direction. More particularly, the staircase structure has a staircase portion SP extending from a bottom step as an end portion in the Z direction toward the X direction, and a dummy staircase portion SPd extending from the bottom step toward the −X direction, the +Y direction, and the −Y direction. The staircase portion SP is formed in a moderately-sloped staircase pattern. The electrode layers 23 in the staircase portion SP each have a step surface (i.e., a terrace area) to which the contact plug 26 is coupled. In contrast, the dummy staircase portion SPd is formed in a steep staircase pattern. The electrode layers 23 in the dummy staircase portion SPd do not have the step surfaces to which the contact plugs 26 are coupled.

As shown in FIG. 2, the step surface of the staircase portion SP at an upper stage side (in other words, at the +X direction side in FIG. 2) is larger in dimension in the Y direction than the step surface of the staircase portion at a lower stage side (in other words, at the −X direction side in FIG. 2). Therefore, the step surface of the staircase portion SP at the upper stage side has a sufficient space at which the plurality of contact plugs 26 can be coupled along the Y direction between the slits adjacent to each other.

Each of the contact plugs 26 is disposed in the interlayer insulating film 21 in the area R1. Each of the contact plugs 26 is, for example, a polysilicon layer or a metal layer. Each of the contact plugs 26 penetrates the insulating film 22 of the staircase portion SP and contacts the step surface of a corresponding one of the electrode layers 23. By contacting the step surface, each of the contact plugs 26 is electrically coupled to the corresponding one of the electrode layers 23. Further, each of the contact plugs 26 is electrically coupled to a corresponding one of the transistors 13.

As shown in FIG. 1, the plurality of contact plugs 26 are arranged in the X direction. As shown in FIG. 1 and FIG. 3, the plurality of contact plugs 26 arranged in the X direction are coupled to the electrode layers 23 at the staircase portion SP in respective stages (i.e., layers) different from each other.

As shown in FIG. 2, in the staircase portion SP at the upper stage side, two contact plugs 26, 26-2 are arranged in the Y direction between the slits ST-1, ST-2 adjacent to each other. The contact plugs 26-2 are each an example of a sixth plug. By arranging the two contact plugs 26, 26-2 in the Y direction between the slits ST-1, ST-2 adjacent to each other, it is possible to reduce the chip size in the X direction. On the other hand, in the staircase portion SP other than the staircase portion SP at the upper stage side, the contact plugs 26 are disposed one by one between the slits adjacent to each other.

It should be noted that as shown in FIG. 2, the two contact plugs 26, 26-2 are also arranged in the Y direction between the slits ST-2, ST-3 adjacent to each other in the staircase portion SP at the upper stage side. The interconnection structure between the slits ST-2, ST-3 is substantially the same as the interconnection structure between the slits ST-1, ST-2. Specifically, the interconnection structure between the slits ST-2, ST-3 has a mirror symmetric shape with reference to an X-Z plane defined at the center of the slit ST-2 with respect to the interconnection structure between the slits ST-1, ST-2. In order to omit redundant descriptions, description will be presented hereinafter with a focus on the interconnection structure between the slits ST-1, ST-2.

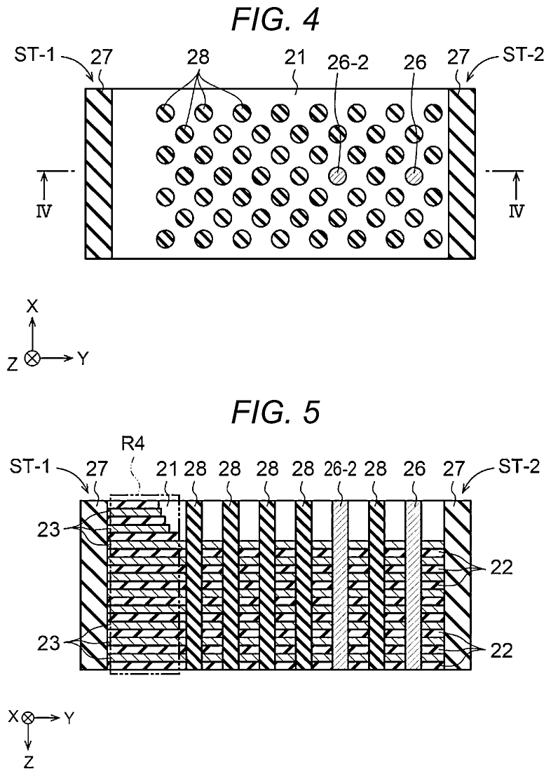

FIG. 4 illustrates a transverse cross-sectional view of the contact plugs 26 of the semiconductor device according to the embodiment. FIG. 5 illustrates a vertical cross-sectional view of the contact plugs 26 of the semiconductor device according to the embodiment. As shown in FIG. 4 and FIG. 5, a plurality of columnar parts 28 penetrating the interlayer insulating film 21 and the stack of films P is disposed in the area R1. When forming the stack of films P, sacrifice films and the insulating films 22 are stacked, and then, the sacrifice films are replaced with the electrode layers 23. The columnar parts 28 are disposed to penetrate the sacrifice films and the insulating films 22 in advance of the replacement. The columnar parts 28 have a function of keeping the mechanical strength of the staircase portion SP during the replacement. The columnar parts 28 have insulating films such as silicon oxide films.

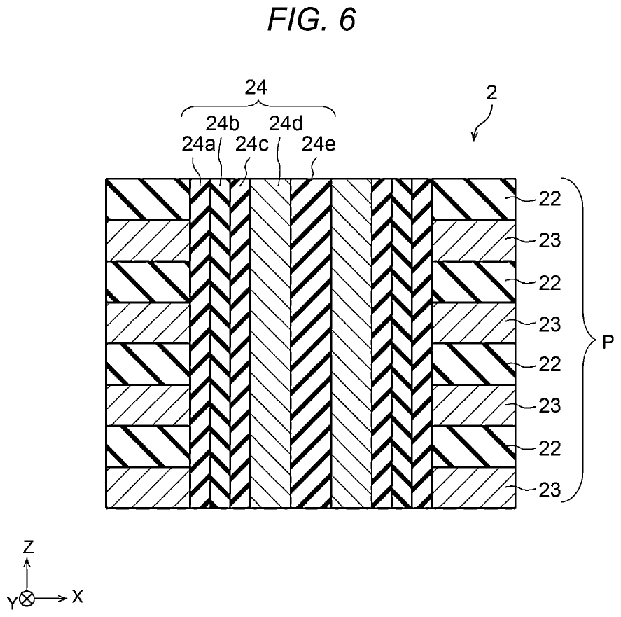

The columnar parts 24 are disposed in the stack of films P in the areas R2, R3. Columnar parts 24 disposed in the area R2 are each an example of a first columnar part. Columnar parts 24 disposed in the area R3 are each an example of a second columnar part. Each of the columnar parts 24 has a columnar shape extending in the Z direction, and penetrates the electrode layers 23. FIG. 6 illustrates a cross-sectional view of the columnar part 24 of the semiconductor device according to the embodiment. As shown in FIG. 6, the columnar part 24 includes a block insulating film 24a, a charge accumulation layer 24b, a tunnel insulating film 24c, a channel semiconductor layer 24d, and a core insulating film 24e formed in series on a side surface of the stack of films P.

The block insulating film 24a is, for example, a silicon oxide film. The charge accumulation layer 24b is an insulating film such as a silicon nitride film. The charge accumulation layer 24b may be a semiconductor layer such as a polysilicon layer. The tunnel insulating film 24c is, for example, a silicon oxide film. The channel semiconductor layer 24d is, for example, a polysilicon layer. The core insulating film 24e is, for example, a silicon oxide film. The channel semiconductor layer 24d in each of the columnar parts 24 is electrically coupled to a corresponding one of the transistors 12.

As shown in FIG. 1, the metal pads 41, the via plugs 42, the interconnection layer 43, the via plugs 44, the interconnection layer 45, the via plugs 46, and the via plugs 47 are disposed in order above the substrate 11. An upper end of each of the via plugs 47 contacts the columnar part 24. Each of the metal pads 41 is bonded to a corresponding one of the metal pads 36 of the circuit part 1. As a result, the columnar part 24 is electrically coupled to one of the transistors 12 via the via plugs 47, 46, the interconnection layer 45, the via plug 44, the interconnection layer 43, the via plug 42, the metal pads 41, 36, the via plug 35, the interconnection layer 34, the via plug 33, the interconnection layer 32, and the contact plug 31.

As shown in FIG. 1, the metal pads 51, the via plugs 52, the interconnection layer 53, and the via plugs 54 are disposed in order above the substrate 11. An upper end of each of the via plugs 54 contacts one of the contact plugs 26. Each of the metal pads 51 is bonded to a corresponding one of the metal pads 36 of the circuit part 1. As a result, the contact plug 26 is electrically coupled to one of the transistors 13 via the via plug 54, the interconnection layer 53, the via plug 52, the metal pads 51, 36, the via plug 35, the interconnection layer 34, the via plug 33, the interconnection layer 32, and the contact plug 31.

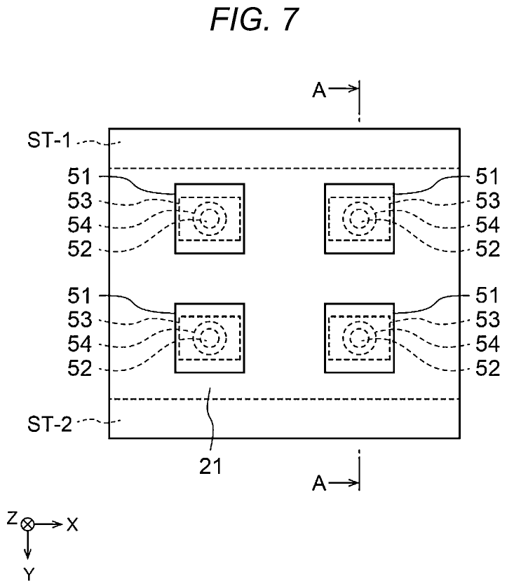

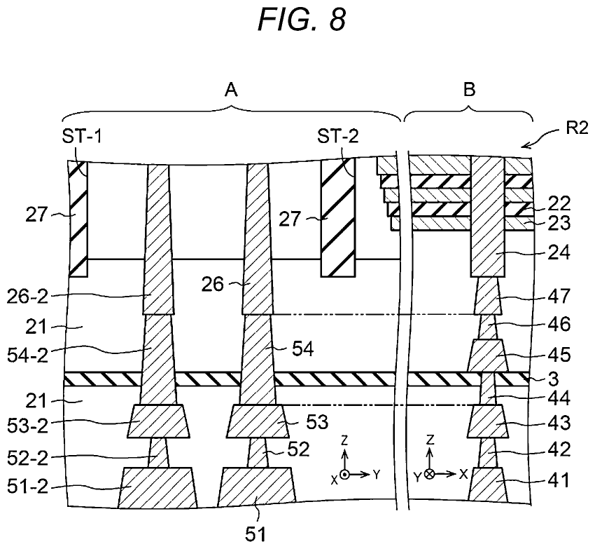

Next, a layout of the interconnections 41 through 47, and 51 through 54 of the array part 2 will be described in further detail. FIG. 7 illustrates a plan view of the interconnection layout of the semiconductor device according to the embodiment. FIG. 8 illustrates a cross-sectional view of the interconnection layout of the semiconductor device according to the embodiment. A cross-sectional surface on the periphery of the contact plug 26 indicated by a symbol A in FIG. 8 corresponds to the cross-sectional surface along the line A-A in FIG. 7. A cross-sectional surface on the periphery of the columnar part 24 indicated by a symbol B in FIG. 8 is a cross-sectional surface in the same direction as the cross-sectional surface in FIG. 1. It should be noted that the cross-sectional surface indicated by the symbol B in FIG. 8 is a cross-sectional surface corresponding to the area R2 of the stack of films P. A cross-sectional surface corresponding to the area R3 of the stack of films P is substantially the same as that indicated by the symbol B in FIG. 8.

The via plug 44 is disposed above (i.e., at the Z direction side of) the substrate 11. The via plug 44 disposed under the area R2 is an example of a first plug. The via plug 44 disposed under the area R3 is an example of an eighth plug. The via plug 44 extends in an upward direction crossing the upper surface of the substrate 11. The via plug 44 includes, for example, tungsten.

The interconnection layer 45 is disposed on the via plug 44. The interconnection layer 45 disposed under the area R2 is an example of a first interconnection. The interconnection layer 45 disposed under the area R3 is an example of a fifth interconnection. The interconnection layer 45 is electrically coupled to the via plug 44. The interconnection layer 45 includes copper. The interconnection layer 45 is, for example, a bit line extending in the Y direction. By including copper, it is possible to form the interconnection layer 45 at low cost.

The interconnection layer 43 is disposed below the via plug 44. The interconnection layer 43 is electrically coupled to the via plug 44. The interconnection layer 43 includes, for example, tungsten.

The via plug 54 is located at the −X direction side of the via plug 44, the −X direction crossing the Z direction. The via plug 54 has the upper end different in level from an upper end of the via plug 44, and a lower end the same in level as a lower end of the via plug 44. In FIG. 8, the level of the upper end and the level of the lower end of the via plug 54 are indicated by dashed-two dotted lines. The via plug 54 includes the same material as that of the via plug 44 such as tungsten.

The contact plug 26 is disposed on the via plug 54. The contact plug 26 is electrically coupled to the via plug 54. The contact plug 26 extends in the Z direction. The contact plug 26 includes tungsten.

The interconnection layer 53 is disposed below the via plug 54. The interconnection layer 53 is located in the same layer level as that of the interconnection layer 43. The interconnection layer 53 includes the same material as that of the interconnection layer 43 such as tungsten.

The upper end of the via plug 54 is located above the upper end of the via plug 44. The via plug 46 is disposed on the interconnection layer 45. The via plug 46 is electrically coupled to the interconnection layer 45. The via plug 46 has an upper end the same in level as the upper end of the via plug 54. In other words, the via plug 54 is a via plug disposed through the plurality of layers, namely a layer in which the via plug 44 is located, a layer in which the interconnection layer 45 is located, and a layer in which the via plug 46 is located. The via plug 54 is larger in outer diameter than the via plug 44.

The via plug 54 is disposed immediately below the contact plug 26. In other words, the via plug 54 is little displaced in the X direction and the Y direction from the contact plug 26. The center of the via plug 54 may coincide with the center of the contact plug 26.

The insulating layer 3 is disposed below the interconnection layer 45. The insulating layer 3 is penetrated by the via plug 44 and the via plug 54. The insulating layer 3 is, for example, a silicon nitride film (i.e., SiCN). The insulating layer 3 has a function of preventing diffusion of copper in the via plug 44.

The via plug 47 is disposed between the via plug 46 and the columnar part 24. The via plug 47 extends in the Z direction. The level of a lower end of the via plug 47 is the same as the level of a lower end of the contact plug 26. The via plug 47 is electrically coupled to the via plug 46 and the columnar part 24.

The contact plug 26-2 is located at the −Y direction side of the contact plug 26 between the slit ST-1 and the slit ST-2. The contact plug 26-2 has an upper end the same in level as the upper end of the contact plug 26, and a lower end the same in level as the lower end of the contact plug 26. The contact plug 26-2 includes tungsten.

A via plug 54-2 is disposed below the contact plug 26-2. The via plug 54-2 is an example of a seventh plug. The via plug 54-2 has an upper end the same in level as the upper end of the via plug 54, and a lower end the same in level as the lower end of the via plug 54. The via plug 54-2 is electrically coupled to the contact plug 26-2. The via plug 54-2 includes tungsten similarly to the via plug 54.

An interconnection layer 53-2 is disposed below the via plug 54-2. The interconnection layer 53-2 is an example of a fourth interconnection. The interconnection layer 53-2 is electrically coupled to the via plug 54-2. The interconnection layer 53-2 includes the same material as that of the interconnection layer 53 such as tungsten.

A via plug 52-2 is disposed below the interconnection layer 53-2. A metal pad 51-2 is disposed below the via plug 52-2. The metal pads 51-2 is bonded to the metal pad 36 of the circuit part 1. Therefore, similarly to the contact plug 26, the contact plug 26-2 is electrically coupled to the transistor 13.

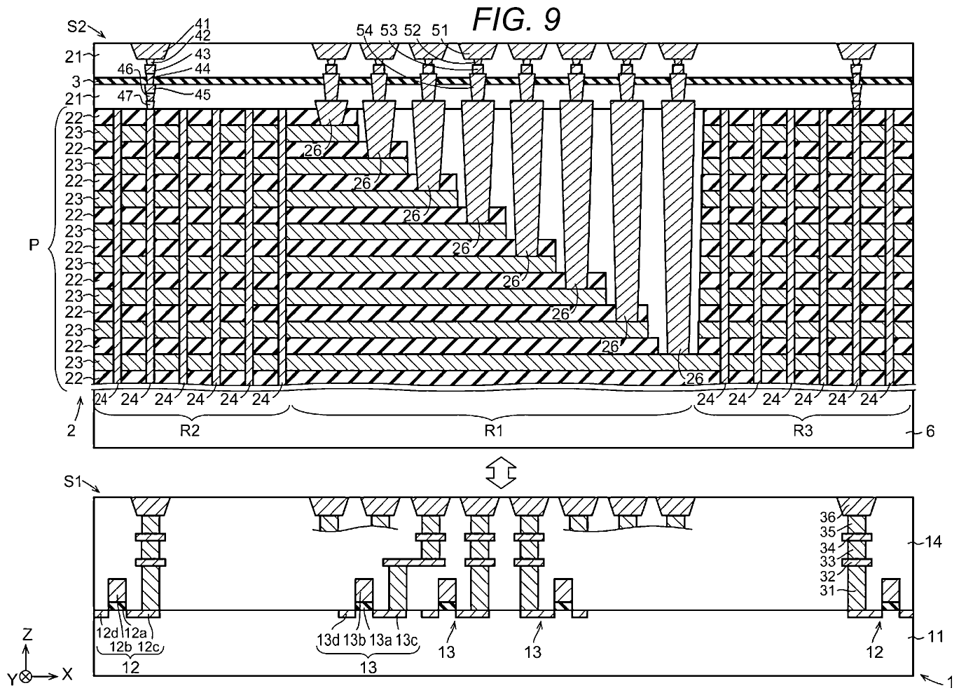

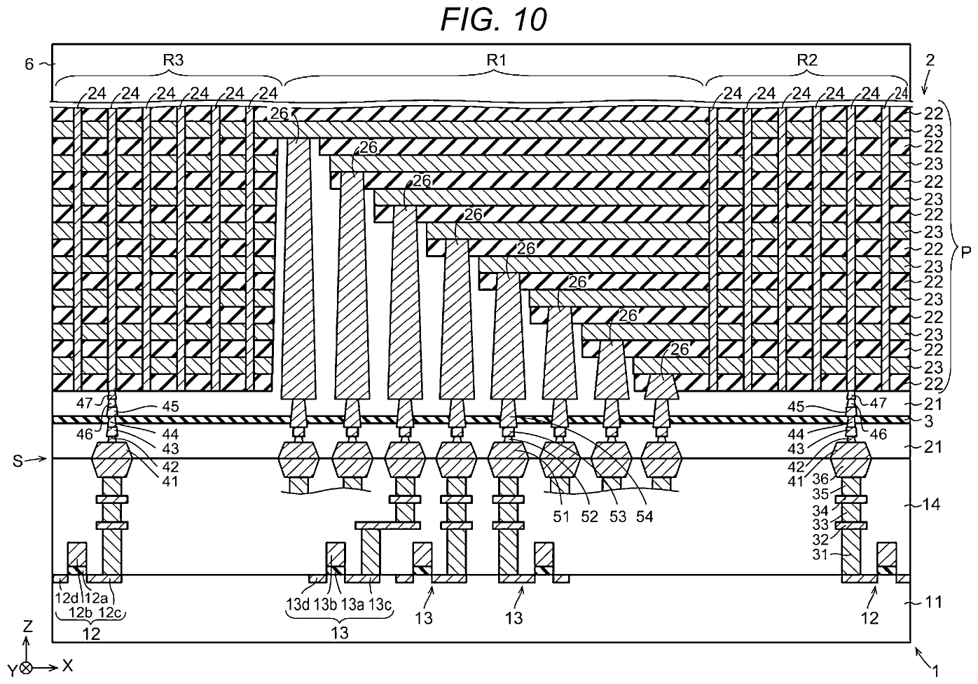

Then, a method of manufacturing the semiconductor device according to the embodiment having the above configuration will be described. FIG. 9 is a cross-sectional diagram to explain a process step of the method of manufacturing the semiconductor device according to the embodiment. FIG. 10 is a cross-sectional diagram to explain process steps, subsequent to that in FIG. 9, of the method of manufacturing the semiconductor device according to the embodiment.

FIG. 9 shows the circuit part 1 included in the circuit wafer and the array part 2 included in the array wafer. The orientation of the array part 2 shown in FIG. 9 is opposite to the orientation of the array part 2 shown in FIG. 1. The semiconductor device according to the present embodiment is manufactured by bonding the circuit wafer and the array wafer to each other as described above. FIG. 9 shows the array part 2 before the array wafer is flipped for performing bonding, and FIG. 10 shows the array part 2 after the array part 2 is flipped in orientation for performing the bonding, and is then bonded to the circuit part 1.

FIG. 9 shows an upper surface S1 of the circuit part 1 and an upper surface S2 of the array part 2. The array part 2 shown in FIG. 9 includes a substrate 6 disposed below the stack of films P. The substrate 6 is, for example, a semiconductor substrate such as a silicon substrate. The substrate 11 is an example of a first substrate. The substrate 6 is an example of a second substrate.

The semiconductor device according to the embodiment is manufactured in such a manner as described. First, the plurality of transistors 12, the plurality of transistors 13, the interlayer insulating film 14, the plurality of contact plugs 31, the interconnection layer 32, the plurality of via plugs 33, the interconnection layer 34, the plurality of via plugs 35, and the plurality of metal pads 36 are formed on the substrate 11 (see FIG. 9). Further, the interlayer insulating film 21, the plurality of insulating films 22, the plurality of electrode layers 23, the plurality of columnar parts 24, and the plurality of contact plugs 26, 26-2 are formed on the substrate 6 (see FIG. 8, FIG. 9). Further, the plurality of metal pads 41, the plurality of via plugs 42, the interconnection layer 43, the plurality of via plugs 44, the interconnection layer 45, the plurality of via plugs 46, and the plurality of via plugs 47 are formed on the substrate 6 (see FIG. 9). Further, the plurality of metal pads 51, 51-2, the plurality of via plugs 52, 52-2, the interconnection layer 53, 53-2, and the plurality of via plugs 54, 54-2 are formed on the substrate 6 (see FIG. 8, FIG. 9).

Then, as shown in FIG. 10, the circuit wafer (more specifically, the circuit part 1) and the array wafer (more specifically, the array part 2) are bonded to each other with mechanical pressure. As a result, the interlayer insulating film 14 and the interlayer insulating film 21 are bonded to each other. Then, the circuit wafer and the array wafer are annealed at 400° C. As a result, the metal pads 36 and the metal pads 41, 51, 51-2 are bonded to each other. The metal pads 36, 41, 51, 51-2 are each, for example, a metal layer including copper (i.e., Cu).

As a result, each of the columnar parts 24 is electrically coupled to a corresponding one of the transistors 12, and each of the contact plugs 26, 26-2 is electrically coupled to a corresponding one of the transistors 13 (see FIG. 10).

Subsequently, the substrate 11 is processed into a thin film with chemical mechanical polishing (abbr. CMP), then the substrate 6 is removed with CMP, and then, the circuit wafer and the array wafer are cut into a plurality of chips. In such a manner, the semiconductor device shown in FIG. 1 is manufactured.

It should be noted that although FIG. 1 shows a boundary surface between the interlayer insulating film 14 and the interlayer insulating film 21, and a boundary surface between the metal pads 36 and the metal pads 41, 51, it is common that these boundary surfaces are not observed after the annealing described above is performed. However, the positions where these boundary y surfaces existed can be estimated by detecting inclinations of the side surfaces of the metal pads 36, inclinations of the side surfaces of the metal pads 41, 51, and position gaps between the metal pads 36 and the metal pads 41, 51.

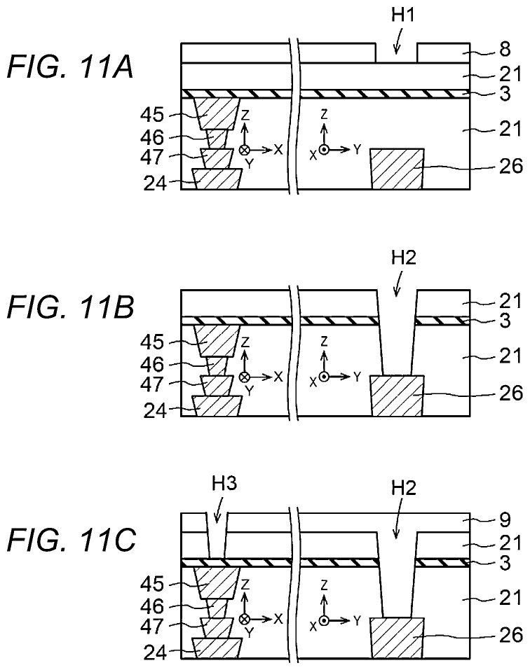

Then, a method of manufacturing a part of the semiconductor device according to the embodiment will be described in further detail. FIGS. 11A through 11C are cross-sectional diagrams to explain the details of the method of manufacturing the semiconductor device according to the embodiment. First, the stack of films P is formed above the substrate 6. After forming the stack of films P, the columnar parts 24 are formed inside the areas R2, R3 of the stack of films P (see FIG. 11A).

After forming the columnar parts 24, the contact plugs 26, 26-2 including tungsten are formed above the substrate 6 (see FIG. 11A, FIG. 8). It should be noted that in FIG. 11A, the illustration of the stack of films P and the contact plugs 26-2 is omitted. The contact plugs 26, 26-2 are formed to be electrically coupled to the electrode layers 23 of the stack of films P in the area R1 of the stack of films P. Further, the via plugs 47 are formed on the columnar parts 24.

After forming the contact plugs 26, 26-2 and the via plugs 47, the interconnection layer 45 including copper is formed above the substrate 6 at a distance in the X direction from the contact plugs 26 (see FIG. 11A). The interconnection layer 45 is formed on the via plugs 46 to be electrically coupled to the columnar parts 24.

After forming the interconnection layer 45, the insulating layer 3 is formed on the interconnection layer 45 (see FIG. 11A). The insulating layer 3 is formed throughout the entire area above the contact plugs 26, 26-2. After forming the insulating layer 3, the interlayer insulating film 21 is formed on the insulating layer 3 (see FIG. 11A).

After forming the interlayer insulating film 21, a mask layer 8 is formed on the interlayer insulating film 21 (see FIG. 11A). After forming the mask layer 8, openings H1 are formed in the mask layer 8 above the via plugs 26, 26-2. The formation of the openings H1 is performed by, for example, a stacked mark process (SMAP).

Then, using reactive ion etching (RIE) using the mask layer 8 with the openings H1 as a mask, holes H2 are formed in the interlayer insulating film 21 (see FIG. 11B). The holes H2 are formed to penetrate the interlayer insulating film 21 and the insulating layer 3 to expose the contact plugs 26, 26-2. After forming the holes H2, the mask layer 8 is removed. The removal of the mask layer 8 is performed with, for example, ashing.

After removing the mask layer 8, a mask layer 9 is formed on the interlayer insulating film 21 to fill the holes H2 (see FIG. 11C). After forming the mask layer 9, openings (not shown) are formed in the mask layer 9 above the interconnection layer 45. The formation of the openings is performed by, for example, SMAP.

Then, by performing RIE with the mask layer 9 having the openings as a mask, holes H3 are formed in the interlayer insulating film 21 (see FIG. 11C). On this occasion, since the insulating layer 3 functions as an etching stopper, the holes H3 are formed to reach the insulating layer 3.

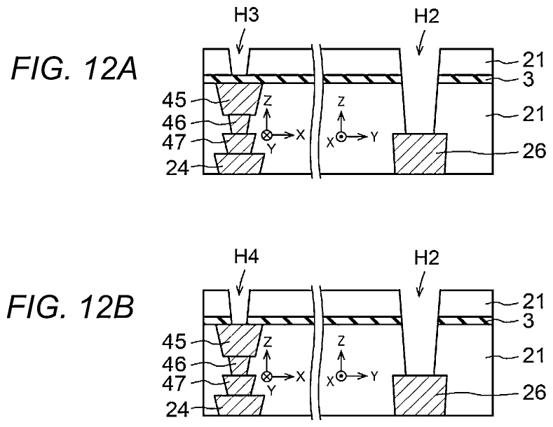

FIGS. 12A and 12B are cross-sectional diagrams to explain process steps, subsequent to that in FIG. 11C, of the method of manufacturing the semiconductor device according to the embodiment. After forming the holes H3, the mask layer 9 is removed (see FIG. 12A). The removal of the mask layer 9 is performed with, for example, ashing.

After removing the mask layer 9, by removing the exposed part of the insulating layer 3 on the interconnection layer 45, holes H4 which penetrate the interlayer insulating film 21 up to the interconnection layer 45 are formed (see FIG. 12B). The removal of the exposed part of the insulating layer 3 on the interconnection layer 45 may be performed with, for example, dry etching. By performing wet etching on the substrate 6 with the holes H2, H4, residuals generated by RIE are removed from the surface of the substrate 6 (see FIG. 12B). A chemical to be used in the wet etching includes, for example, hydrochloric acid (i.e., HCL), dilute hydrofluoric acid (i.e., DHF), and choline (i.e., TMY).

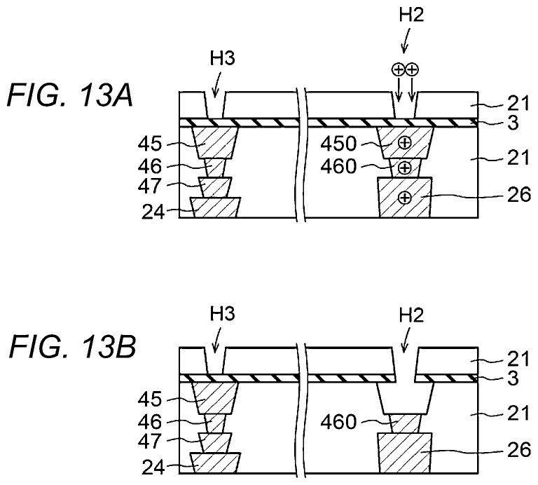

FIGS. 13A and 13B are cross-sectional diagrams to explain a method of manufacturing a semiconductor device according to a first comparative example. In FIG. 13A, a symbol “+” represents a charge, namely an ion, that appears during RIE. Here, as the first comparative example, an example in which an interconnection layer 450 including copper is formed instead of the via plug 54 above the contact plug 26 is described. In the first comparative example, when the hole H2 is formed (see FIG. 13A) above the contact plug 26 using RIE, charges are accumulated in a capacitance between the contact plug 26 and the electrode layer 23. It should be noted that when forming the hole H3 above the columnar part 24, charges are accumulated in a capacitance between the columnar part 24 and the electrode layer 23. However, the capacitance between the columnar part 24 and the electrode layer 23 is smaller than the capacitance between the contact plug 26 and the electrode layer 23. Therefore, an amount of the charges accumulated in the capacitance between the columnar part 24 and the electrode layer 23 is negligibly small compared to an amount of the charges accumulated in the capacitance between the contact plug 26 and the electrode layer 23.

When the charges are accumulated in the capacitance between the contact plug 26 and the electrode layer 23, the interconnection layer 450 is dissolved by the chemical to be dispersed when performing the wet etching after forming the hole H2 (see FIG. 13B). This is caused by a battery effect based on a correlation between a potential of copper and a pH value of the chemical. Specifically, during the wet etching, by the charges accumulated in the capacitance between the contact plug 26 and the electrode layer 23 moving to the interconnection layer 450, the interconnection layer 450 takes a potential higher than 0 [V]. When the interconnection layer 450 formed of copper c chemical (e.g., hydrochloric acid and dilute hydrofluoric acid) in the state of having a potential higher than 0 [V], the interconnection layer 450 is eluted into the chemical due to the battery effect. For that reason, in the first comparative example, electrical characteristics the deteriorate due to the disappearance of the interconnection layer 450.

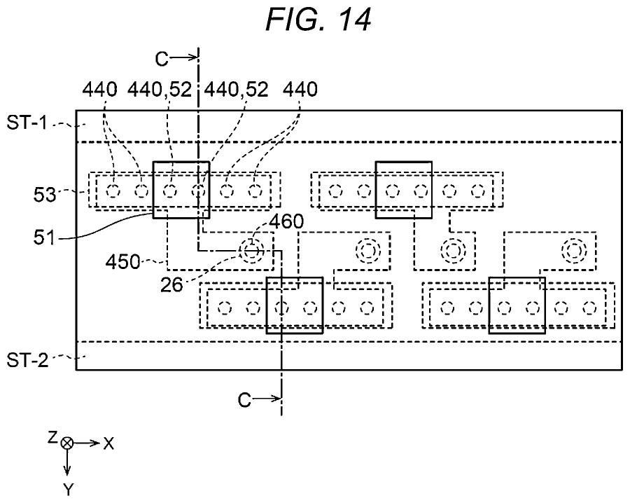

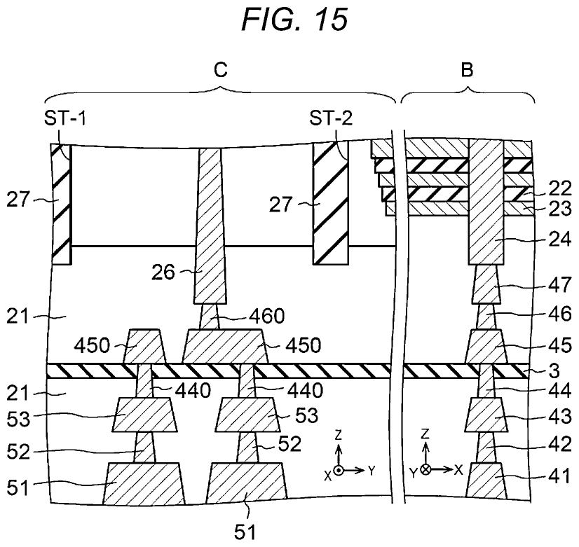

Next, as a second comparative example, an example in which a plurality of via plugs 440 is coupled to the interconnection layer 450 is described. FIG. 14 illustrates a plan view of an interconnection layout of a semiconductor device which is manufactured using a method of manufacturing a semiconductor device according to the second comparative example. FIG. 15 illustrates a cross-sectional view of the interconnection layout of the semiconductor device which is manufactured using the method of manufacturing the semiconductor device according to the second comparative example. In the second comparative example, six via plugs 440 are coupled to one interconnection layer 450. Thus, during the wet etching, the charges accumulated in the capacitance between the contact plug 26 and the electrode layer 23 are dispersed and move to six positions (i.e., positions corresponding to six holes H2 in which the six via plugs 440 are respectively formed) of the interconnection layer 450 contacting the chemical. Thus, the potential of the interconnection layer 450 contacting the chemical is reduced to about one-sixth at the six positions compared to when one via plug 440 is coupled to one interconnection layer 450 (see FIG. 13A). By reducing the potential of the interconnection layer 450, the elution of the interconnection layer 450 due to the battery effect is prevented. Further, even if partial elution of the interconnection layer 450 occurs due to the battery effect, conduction between the metal pad 51 and the contact plug 26 is maintained by at least one via plug 440 coupled to the interconnection layer 450 which remains. However, in the second comparative example, the size in the X direction of the interconnection layer 450 increases from the necessity that the six via plugs 440 are coupled to the interconnection layer 450. Further, the increase in the size in the X direction of the interconnection layer 450 makes it difficult to keep the margin for forming the two contact plugs 26, 26-2 between the slits ST-1, ST-2 adjacent to each other. Therefore, in the second comparative example, even though the deterioration of the electrical characteristic can be suppressed to some extent, the chip size cannot be reduced.

In contrast, as described above, in the embodiment, before the wet etching, the holes H2 are formed to expose the contact plugs 26 instead of forming the interconnection layer 450 including copper on the contact plugs 26. Thus, it is possible to structurally avoid the elution of the interconnection layer 450 formed of copper and the increase in size of the interconnection layer 450. Therefore, according to the embodiment, it is possible to miniaturize the chip size while preventing the deterioration of the electrical characteristics.

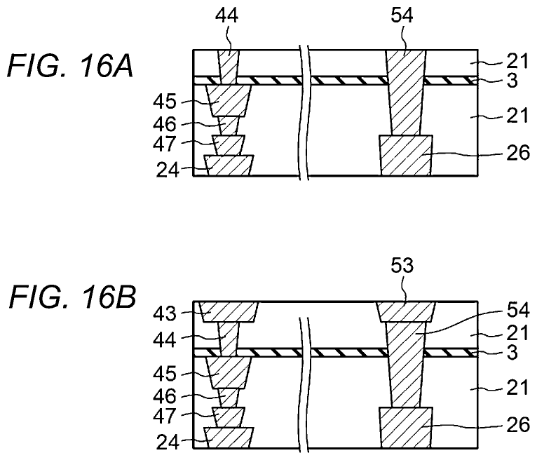

FIGS. 16A and 16B are cross-sectional diagrams to explain process steps, subsequent to that in FIG. 12B, of the method of manufacturing the semiconductor device according to the embodiment. After performing the wet etching of the substrate 6, the via plugs 44 including tungsten are formed on the interconnection layer 45. The formation of the via plugs 44 is performed to fill in the holes H4 (see FIG. 12B). Further, the via plugs 54 including tungsten are formed on the contact plugs 26 at the same time as the formation of the via plugs 44. The formation of the via plugs 54 is performed to fill the holes H2. After forming the via plugs 44, 45, tungsten on the interlayer insulating film 21 is removed with CMP (see FIG. 16A).

After performing CMP, the interconnection layer 43 including tungsten is formed on the via plugs 44. The interconnection layer 53 including tungsten is formed on the via plugs 54 at the same time as the formation of the interconnection layer 43 (see FIG. 16B).

As described hereinabove, the semiconductor device according to the embodiment includes the substrate 11, the via plugs 44, the interconnection layer 45, the interconnection layer 43, the via plugs 54, the contact plugs 26, and the interconnection layer 53. The via plugs 44 are disposed above the substrate 11, and extend in the Z direction crossing the upper surface of the substrate 11. The interconnection layer 45 is disposed on the via plugs 44, and includes copper. The interconnection layer 43 is disposed below the via plugs 44. The via plug 54 is located at the −X direction side of the via plug 44, the −X direction crossing the Z direction. The via plug 54 has the upper end different in level from the upper end of the via plug 44, and the lower end the same in level as the lower end of the via plug 44. The contact plug 26 is disposed on the via plug 54, extends in the Z direction, and includes tungsten. The interconnection layer 53 is disposed below the via plugs 54. Thus, since there is no need to dispose the interconnection layer 450 (see FIG. 13A through FIG. 15) including copper below the contact plugs 26, it is possible to avoid the deterioration of the electrical characteristics due to the disappearance of the interconnection layer 450 and the increase in size of the interconnection layer 450. Therefore, according to the embodiment, it becomes possible to miniaturize the chip size while preventing the deterioration of the electrical characteristics.

Further, in the embodiment, the upper end of the via plug 54 is located above the upper end of the via plug 44. Further, the via plug 46 having the upper end the same in level as the upper end of the via plug 54 is disposed on the interconnection layer 45. Thus, it is possible to minimize the manufacturing man-hour of the interconnections (i.e., the via plugs 54) for electrically coupling the contact plug 26 and the interconnection layer 53 to each other.

Further, according to the embodiment, by disposing the via plug 54 immediately below the contact plug 26 it becomes possible to further miniaturize the chip size.

Further, according to the embodiment, since the via plugs 44 and the via plugs 54 include the same material, it is possible to form the via plugs 44, 54 at the same time. Thus, it is possible to reduce the manufacturing man-hour of the semiconductor device.

Further, according to the embodiment, by forming the via plugs 54 to be larger in outer diameter than the via plugs 44, it is possible to appropriately form the via plugs 54 having the height that spans the plurality of layers.

Further, according to the embodiment, since the interconnection layer 43 and the interconnection layer 53 include the same material, it is possible to form the interconnection layers 43, 53 at the same time. Thus, it is possible to reduce the manufacturing steps of the semiconductor device.

Further, in the embodiment, an insulating layer 3 penetrated by the via plugs 44, 54 is disposed below the interconnection layer 45. Thus, it is possible to prevent copper in the interconnection layer 45 from dispersing into the interlayer insulating film 21.

Further, the semiconductor device according to the embodiment further includes the stack of films P, the columnar parts 24, and the via plugs 47. The stack of films P includes the plurality of electrode layers 23 which are stacked in the Z direction, and are insulated from each other. The stack of films P includes the area R1 which is located above the contact plugs 26, and is electrically coupled to the contact plugs 26. The stack of films P further includes the area R2 which is located at the +X direction side of the area R1, and is located above the via plug 46. The columnar parts 24 are disposed in the area R2. The columnar part 24 includes the semiconductor layer 24d extending in the Z direction, and the charge accumulation layer 24b disposed between the semiconductor layer 24d and the electrode layer 23. The via plug 47 is disposed between the via plug 46 and the columnar part 24, and extends in the Z direction. Thus, in the three-dimensional semiconductor storage device, it becomes possible to miniaturize the chip size while preventing the deterioration of the electrical characteristics.

Further, the semiconductor device according to the embodiment further includes the slit ST-1, the slit ST-2, the contact plugs 26-2, the via plugs 54-2, and the interconnection layer 53-2. The slit ST-1 extends in the X direction to segmentalize the stack of films P. The slit ST-2 is located at the Y direction side of the slit ST-1 across the contact plugs 26. The slit ST-2 extends in the X direction to segmentalize the stack of films P. The contact plug 26-2 is located at the +Y direction side of the contact plug 26 between the slit ST-1 and the slit ST-2. The contact plug 26-2 has the upper end the same in level as the upper end of the contact plug 26, and the lower end the same in level as the lower end of the contact plug 26, and includes tungsten. The via plug 54-2 is disposed below the contact plug 26-2. The via plug 54-2 has the upper end the same in height as the upper end of the via plug 54, and the lower end the same in level as the lower end of the via plug 54. The interconnection layer 53-2 is disposed below the via plugs 54-2. Accordingly, since it is possible to dispose the two contact plugs 26, 26-2 along the Y direction between the slits ST-1, ST-2 adjacent to each other, it is possible to effectively miniaturize the chip size.

Further, according to the embodiment, since the via plugs 54-2 include the same material as those of the via plugs 44, 54, it is possible to form the via plugs 44, 54, and 54-2 at the same time. Thus, it is possible to reduce the manufacturing step of the semiconductor device while effectively miniaturizing the chip size.

Further, according to the embodiment, since the interconnection layer 53-2 includes the same material as those of the interconnection layers 43, 53, it is possible to form the interconnection layers 43, 53, and 53-2 at the same time. Thus, it is possible to reduce the manufacturing step of the semiconductor while effectively miniaturizing the chip size.

Further, in the embodiment, the stack of films P further includes the area R3 and the area R4. The area R3 is located at the −X direction side of the area R1, and is provided with the columnar parts 24 similarly to the area R2. The area R4 is located at the +Y direction side of the area R1. The area R4 electrically couples the electrode layers 23 in the area R2 and the electrode layers 23 in the area R3 to each other. Thus, since it is possible to form the staircase structure in the central portion of the cell area, it is possible to reduce the lengths and the resistance values of the electrode layers 23 compared to when forming the staircase structure outside the cell area.

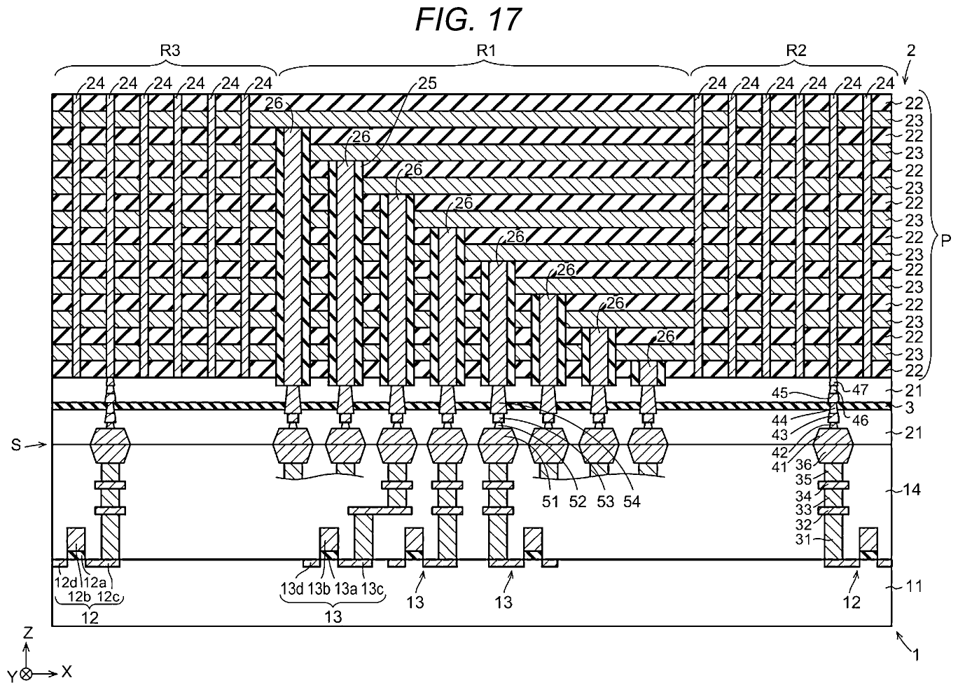

Then, a modified example of the embodiment will be described. The embodiment in which the stack of films P in the area R1 has the staircase structure is hereinabove described. In contrast, as shown in FIG. 17, the stack of films P in the area R1 may continue to the stack of films P in the areas R2, R3 except the contact plugs 26 and penetration portions with insulating layers 25 disposed on the outer circumferences of the contact plugs 26.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a first plug disposed above the substrate and extending in a first direction that crosses an upper surface of the substrate;
a first interconnection disposed above and electrically connected to the first plug, the first interconnection containing copper;
a second interconnection disposed below and electrically connected to the first plug;
a second plug disposed above the substrate and extending in the first direction, an upper end of the second plug being different in level from an upper end of the first plug and a lower end of the second plug being same in level as a lower end of the first plug;
a third plug disposed above and electrically connected to the second plug and extending in the first direction, the third plug containing tungsten; and
a third interconnection disposed below and electrically connected to the second plug.

2. The semiconductor device according to claim 1, further comprising:
a fourth plug disposed above and electrically connected to the first interconnection, an upper end of the fourth plug being same in level as the upper end of the second plug, wherein
the upper end of the second plug is above in level with respect to the upper end of the first plug.

3. The semiconductor device according to claim 2, further comprising:
a stack of films including a plurality of electrode layers stacked in the first direction and insulated from each other, the stack of films including:
a first area located above the third plug, the third plug being electrically connected to one of the electrode layers; and
a second area located above the fourth plug;
a first columnar part extending through the stack of films in the first direction in the second area, the first columnar part including a first semiconductor layer extending in the first direction and a first charge accumulation layer disposed between the first semiconductor layer and the plurality of electrode layers; and
a fifth plug disposed between the fourth plug and the first columnar part and extending in the first direction.

4. The semiconductor device according to claim 3, wherein
the first interconnection serves as a bit line.

5. The semiconductor device according to claim 3, further comprising:
a first segmentation part extending in a second direction that is along the upper surface of the substrate;
a second segmentation part extending in the second direction, the second segmentation part being adjacent to the first segmentation part in a third direction that is along the upper surface of the substrate, with the stack of films therebetween,
a sixth plug extending in the first direction below the first area of the stack films, the sixth plug being adjacent to the third plug in the third direction and containing tungsten, an upper end of the sixth plug being same in level as an upper end of the third plug and a lower end of the sixth plug being same in level as a lower end of the third plug;
a seventh plug disposed below and electrically connected to the sixth plug, an upper end of the seventh plug being same in level as the upper end of the second plug and a lower end of the seventh plug being same in level as the lower end of the second plug; and
a fourth interconnection below and disposed electrically connected to the seventh plug.

6. The semiconductor device according to claim 5, wherein
the seventh plug includes a same material as the materials of the first plug and the second plug.

7. The semiconductor device according to claim 5, wherein
the second interconnection, the third interconnection, and the fourth interconnection are formed of a same material.

8. The semiconductor device according to claim 3, wherein
the stack of films further includes:
a third area adjacent to the first area in the second direction, with the first area between the second area and the third area; and
a fourth area connecting the first area and the third area in the second direction, the fourth area being adjacent to the first area in the third direction, and
the semiconductor device further comprises a second columnar part extending through the stack of films in the first direction in the third area, the second columnar part including a second semiconductor layer extending in the first direction and a second charge accumulation layer disposed between the second semiconductor layer and the plurality of electrode layers.

9. The semiconductor device according to claim 8, further comprising:
a fifth interconnection disposed below the third area and electrically connected to the second columnar part, the fifth interconnection containing copper; and
an eighth plug disposed below and electrically connected to the fifth interconnection and extending in the first direction, an upper end of the eighth plug being same in level as the upper end of the first plug and a lower end of the eighth plug being same in level as the lower end of the first plug.

10. The semiconductor device according to claim 1, wherein
the second plug is disposed immediately below the third plug.

11. The semiconductor device according to claim 1, wherein
the first plug and the second plug are formed of a same material.

12. The semiconductor device according to claim 1, wherein
an outer diameter of the second plug at a level is larger than an outer diameter of the first plug at the level.

13. The semiconductor device according to claim 1, wherein
the second interconnection and the third interconnection are formed of a same material.

14. The semiconductor device according to claim 1, further comprising:
an insulating layer disposed above and along the upper surface of the substrate and below the first interconnection, the first plug and the second plug penetrating the insulating layer.

15. The semiconductor device according to claim 1, further comprising:
a first transistor disposed on the substrate and electrically connected to the second interconnection; and
a second transistor disposed on the substrate and electrically connected to the third interconnection.

16. A method of manufacturing a semiconductor device, comprising:
forming, above a first substrate, a third plug extending in a first direction crossing an upper surface of the first substrate, the third plug containing tungsten;
forming, above the first substrate, a first interconnection containing copper at a distance in a second direction along the upper surface of the first substrate from the third plug;
forming, on the first interconnection, a first plug extending in the first direction;
forming, on the third plug, a second plug extending in the first direction, an upper end of the second plug being same in level as an upper end of the first plug and a lower end of the second plug being different in level from a lower end of the first plug;
forming a second interconnection on the first plug; and
forming a third interconnection on the second plug.

17. The method according to claim 16, wherein
the first plug and the second plug are formed by a same process step.

18. The method according to claim 16, further comprising:
forming an insulating layer on the first interconnection;
forming an insulating film on the insulating layer;
forming a first hole that penetrates the insulating film and the insulating layer and exposes the third plug;
forming a second hole that penetrates the insulating film and the insulating year and exposes the first interconnection; and
treating the first hole and the second hole with a chemical, wherein
the first plug is formed in the second hole after the second hole is treated with the chemical, and
the second plug is formed in the first hole after the first hole is treated with the chemical.

19. The method according to claim 16, further comprising:
forming, above the first substrate, a stack of films including a plurality of electrode layers stacked in the first direction and insulated from each other, the stack of films including a first area and a second area adjacent to the first area in the second direction;
forming, in the second area, a first columnar part extending through the stack of films in the first direction, the first columnar part including a first semiconductor layer extending in the first direction and a first charge accumulation layer disposed between the first semiconductor layer and the plurality of electrode layers;
forming a first transistor and a second transistor on a second substrate;
bonding, after the second interconnection and the third interconnection are formed, the first substrate and the second substrate to each other to electrically couple the second interconnection to the first transistor and electrically couple the third interconnection to the second transistor; and
removing the first substrate, wherein
the first interconnection is electrically connected to the first columnar part, and
the third plug is electrically connected to one of the plurality of electrode layers in the first area.
